(19) United States
(12) Patent Application Publication
(10) Pub. No.: US 2013/0215696 A1
(43) Pub. Date: Aug. 22, 2013

(54) ANTI-FUSE CIRCUIT OF SEMICONDUCTOR DEVICE AND METHODS OF TESTING INTERNAL CIRCUIT BLOCK THEREOF

(71) Applicant: SAMSUNG ELECTRONICS CO., LTD., (US)

(72) Inventors: Ahn Choi, Gyeonggi-do (KR); Kyung-Rak Choi, Seoul (KR)

(73) Assignee: SAMSUNG ELECTRONICS CO., LTD., Gyeonggi-do (KR)

(21) Appl. No.: 13/735,094

(22) Filed: Jan. 7, 2013

(30) Foreign Application Priority Data
Feb. 22, 2012 (KR) 10-2012-0017990

(51) Int. Cl. G11C 29/04

(52) U.S. Cl. CPC G11C 29/04
USPC 365/201

(57) ABSTRACT

A method of testing an internal circuit block of anti-fuse circuit and a circuit for detecting a defect in the operation of the internal circuit block such as a defect in a sensing part or in a transfer part thereof. Forming a sensing part testing path in a sensing part connected to an output terminal of anti-fuse array; obtaining a sensing output signal through a sense amplifier in the sensing part by applying a test signal through the sensing part testing path while the anti-fuses in the anti-fuse array are not ruptured; detecting defects in the sensing part by comparing the sensing output signal with a reference data corresponding to the test signal. Defectively operating chips may be effectively repaired by adjusting control terminals within a specific control range upon detection of a defect of internal circuit block.

### CROSS-REFERENCE TO RELATED APPLICATIONS

This U.S. non-provisional patent application claims priority under 35 U.S.C. §119 of Korean Patent Application No. 10-2012-0017990, filed on Feb. 22, 2012, the entire contents of which are hereby incorporated by reference.

### BACKGROUND

1. Technical Field

The present inventive concept relates to semiconductor devices, and more particularly, to a method of testing an internal circuit block of anti-fuse circuit and the anti fuse circuit of semiconductor device.

2. Discussion of the Related Art

Generally, an anti-fuse circuit includes an anti fuse array. The anti-fuse array is composed of a plurality of anti fuses arranged in the matrix form of row and column.

An anti-fuse circuit can be applied in a semiconductor memory device such as a dynamic random access memory to support a repair scheme for repairing a failed memory cell by effectively replacing it with a redundancy memory cell previously built in.

A repair method using an anti-fuse can overcome the limitations of a repair method using a conventional fuse. Thus, since the repair method using a conventional fuse is performed at the wafer level, when a failed memory cell exists in a semiconductor device at a package level, a repair fails. A limitation of the fuse method can be overcome by applying the anti-fuse to perform a repair. The anti-fuse has an electrical characteristic opposite to a fuse so that an anti-fuse can be programmed to repair a failed cell even at a package level.

An anti-fuse circuit may include an anti-fuse array, a sensing part and a transfer part. The sensing part sensing program information of anti-fuse and the transfer part transmitting a sensing output of the sensing part to a decoder are included in an internal circuit block of the anti-fuse circuit.

If internal circuit blocks of a chip do not operate normally even though an anti-fuse of anti-fuse array is programmed normally, the chip is finally judged to be failed chip.

Therefore, a test should be performed on the internal circuit blocks to check whether the internal circuit blocks of anti-fuse circuit operate normally or not. Typically, a test of the internal circuit block has been performed in a state that an anti-fuse in the anti-fuse array is ruptured (i.e., programmed). When detecting whether the sensing part and the transfer part are failed or not, a rupture cell check mode (RCCM) or a wafer repair check operation is performed in a state that anti-fuse cells of the anti-fuse array are ruptured (i.e., programmed).

However, since an anti-fuse is one time program (OTP) cell, an anti-fuse cell which is once ruptured cannot have initial state information that existed before the anti-fuse cell was programmed. An anti-fuse cell in a state that is not ruptured (i.e., an initial state) has information of “0”, and an anti-fuse cell in a ruptured state (a programmed state) has information of “1”. The anti-fuse cell having information of “1” cannot permanently have information of “0” even by any method.

### SUMMARY

Embodiments of the inventive concept provide a method of testing an internal circuit block of anti-fuse circuit. The anti-fuse circuit may be employed to select rows or columns in a volatile semiconductor memory device, to select redundancy memory cells therein. The anti-fuse circuit conventionally includes a sensing part connected to an output terminal of anti-fuse array, configured to output a sensing output signal based on the data stored in the anti-fuse array. The method may include forming a sensing part testing path (formed in or parallel to the sensing part) connected to an output terminal of anti-fuse array; obtaining a sensing output signal through a sense amplifier in the sensing part by applying a test signal through the sensing part testing path while the anti-fuses in the anti-fuse array are not ruptured; and detecting defects in the operation of the sensing part by monitoring the sensing output signal (e.g., by comparing the sensing output signal with the test signal).

Exemplary embodiments of the inventive concept also provide a method of testing an internal circuit block of anti-fuse circuit. The method may include forming a transfer part testing path in a transfer part connected to a sensing output terminal of sensing part (the sensing part being for sensing an output of anti-fuse array); obtaining transfer data through the transfer part by applying test data through the transfer part testing path while an anti-fuses in the anti-fuse array are not ruptured; and detecting the transfer part for defects by monitoring the transfer data.

Exemplary embodiments of the inventive concept also provide an anti-fuse circuit of semiconductor device. The anti-fuse circuit of semiconductor device may include an anti-fuse array comprising a plurality of anti-fuses; a sensing part connected to an output terminal of the anti-fuse array; a transfer part connected to a sensing output terminal of the sensing part; a test signal input part providing a test signal to the output terminal of the anti-fuse array in response to an activation signal being applied while anti-fuses in the anti-fuse array are not ruptured; and a monitoring part detecting the sensing part for defects by monitoring a sensing output signal while the sensing part receives the test signal to generate the sensing output signal at the sensing output terminal while the sensing part receives the test signal.

Embodiments of inventive concepts will be described more fully hereinafter with reference to the accompanying drawings, in which embodiments of the invention are shown. This inventive concept may, however, be embodied in many different forms and should not be construed as limited to the embodiments set forth herein. Rather, these embodiments are provided so that this disclosure will be thorough and complete, and will fully convey the scope of the inventive concept to those skilled in the art. In the drawings, the size and relative sizes of layers and regions may be exaggerated for clarity. Like numbers refer to like elements throughout.

### BRIEF DESCRIPTION OF THE FIGURES

Preferred embodiments of the inventive concept will be described below in more detail with reference to the accompanying drawings, in which:

FIG. 1 is a block diagram of semiconductor memory device to which some embodiments of the inventive concept are applied;

FIG. 2 is a block diagram of anti-fuse circuit in the semiconductor memory device of FIG. 1;

FIG. 3 is a detailed circuit diagram of internal circuit block of the anti-fuse circuit including a sensing amplifier as shown in FIG. 2;

FIG. 4 is a detailed circuit diagram of internal circuit block of the anti-fuse circuit including a transfer part as shown in FIG. 2;

FIGS. 5 through 8 are timing diagrams provided to explain an exemplary circuit operation of the circuit block shown in FIG. 4;

FIG. 9 is a block diagram of an exemplary embodiment of the inventive concept applied to a memory system; and

FIG. 10 is a block diagram of an exemplary embodiment of the inventive concept applied to an electronic device.

### DETAILED DESCRIPTION OF THE EXEMPLARY EMBODIMENTS

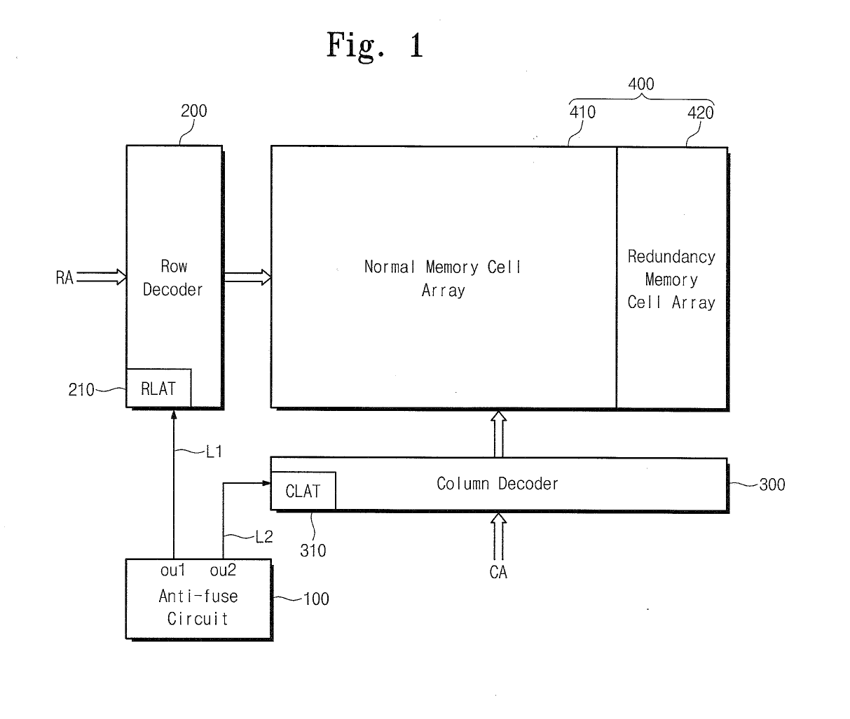

FIG. 1 is a block diagram of semiconductor memory device to which some exemplary embodiments of the inventive concept are applied.

Referring to FIG. 1, the semiconductor memory device includes a row decoder 200, a column decoder 300, a normal memory cell array 410, a redundancy memory cell array 420 and an anti-fuse circuit 100.

The normal memory cell array 410 of memory cell array 400 includes a plurality of memory cells arranged in a matrix form of row and column. In the case that the semiconductor memory device is a DRAM, a unit memory cell may include and consist essentially of one access transistor and one capacitor. If any memory cell of the normal memory cell array 410 is proved to be failed during a test stage, the failed memory cell can be repaired by a memory cell of the redundancy memory cell array 420. When a fail address selecting a failed memory cell is applied, the future selection of the failed memory cell is blocked and a redundancy memory cell is selected instead. The repair information like this is fixed in the anti-fuse circuit 100.

The row decoder 200 decodes a row address RA to select a row of the memory cell array 400. The row decoder 200 includes a row latch RLAT 210 for latching a defect row address applied through a line L1. The row latch RLAT 210 has a structure such as a static random access memory cell and includes a plurality of latches. When a defect row address is applied, the row decoder 200 causes a corresponding redundancy row in the memory cell array 420 be selected on the basis of information stored in the row latch 210.

The column decoder 300 decodes a column address CA to select a column of the memory cell array 400. The column decoder 300 includes a column latch CLAT 310 latching a defect column address applied through a line L2. The column latch CLAT 310 has a structure such as a static random access memory cell and includes a plurality of latches. When a defect column address is applied, the column decoder 300 makes a corresponding redundancy column in the memory cell array 420 be selected on the basis of information stored in the column latch CLAT 310.

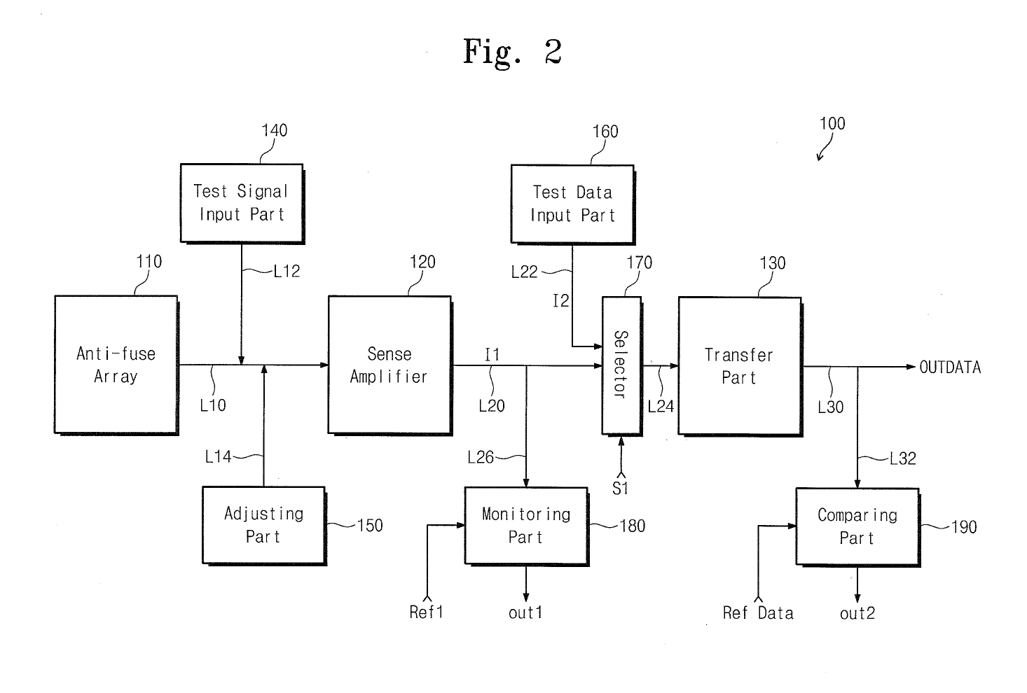

The anti-fuse circuit 100 may be constituted with a circuit block structure like as shown in FIG. 2. The anti-fuse circuit 100 may output row redundancy enable data for a row repair through a first output stage OU1 and may output column redundancy enable data for a column repair through a second output stage OU2.

In FIG. 1, the anti-fuse circuit 100 is applied to a semiconductor memory device such as a DRAM. However, the anti-fuse circuit 100 may be applied to a volatile semiconductor memory such as SRAM or to another nonvolatile semiconductor memory.

FIG. 2 is a block diagram of anti-fuse circuit of FIG. 1.

Referring to FIG. 2, the anti-fuse circuit 100 basically includes an anti-fuse array 110, a sensing part including a sense amplifier 120 and a transfer part 130.

The anti-fuse circuit 100 includes an anti-fuse array 110, a sense amplifier 120, a transfer part, a test signal input part 140, an adjusting part 150, a test data input part 160, a monitoring part 180, a selector 170 and a comparing part 190.

When anti-fuses in the anti-fuse array 110 exist in a state that is not ruptured, the test signal input part 140 provides a test signal to an output terminal L10 of the anti-fuse array 110 in response to an activation signal being applied. The test signal is applied to the output terminal L10 of the anti-fuse array through an output terminal L12 of the test signal input part 140. The test signal is an alternative input applied to the sense amplifier 120.

Even if the sense amplifier 120 is proved to be defective, if the sense amplifier 120 is in a range that can be adjusted to reliable operation, the adjusting part 150 performs a function of adjusting the control factor of the sense amplifier 120. The adjusting part 150 can adjust a threshold of the sense amplifier 120 by adjusting an input leakage current of the sense amplifier 120 through a line L14. The control factor of the sense amplifier 120 can be a sensing reference value of the sensing amplifier 120 and an input leakage value of the sense amplifier 120. Since a defective sense amplifier can be changed to an operative sense amplifier by adjusting the control factor, a defect of internal circuit block can be cured.

The monitoring part 180 monitors a sensing output signal being output by the sense amplifier 120 through a line L20 to detect whether the sensing part including the sensing amplifier 120 is defective or not. The sensing output signal is a signal output from the sense amplifier 120 while in a state that anti-fuses in the anti-fuse array 110 are not ruptured. In this case, the test signal is applied as an input of the sense amplifier 120 through the testing pass line L12 of the sensing part. The monitoring part 180 outputs to an output terminal out1 a result obtained by comparing the sensing output signal with a reference comparative signal Ref1. The result output at terminal out1 is a defect adjustment signal of sensing part.

In the case that the sensing part receives the test signal to generate a sensing output signal on the sensing output terminal L20, the monitoring part 180 monitors the sensing output signal to detect whether the sensing part is defective or not. When a high level signal is applied as an input of the sense amplifier 120 through the sensing part testing pass line L12, the monitoring part 180 compares the reference comparative signal Ref1 having a high level with the signal of the sensing output terminal. Preferably, an operation of sense amplifier 120 is normal only when the high level signal exists in a sensing output terminal. Thus, if levels of two comparative inputs are different from each other, the defect adjustment signal of the sensing part may have a high level. In the case that a defect adjustment signal of sensing part has a high level while levels of two comparative inputs have an insignificant difference, a defect of the sense amplifier 120 can be cured through adjustment of the adjusting part 150.

Thus, in the case that the sensing part receives the test signal to generate a sensing output signal on the sensing output terminal L20, the monitoring part 180 monitors the sensing output signal to detect whether the sensing part is defective or not. In this case, anti-fuses in the anti-fuse array 110 exist in a not ruptured state.

When anti-fuses in the anti-fuse array 110 exist in a not ruptured state, the test input part 160 applies data to the sensing output terminal L20.

The selector 170 as a select part alternately applies (multiplexes) one of a test data 12 and a sensing data I1 of the sensing output terminal L20 to the output transfer part 130 according to a select control signal S1 being applied. The test data 12 is applied to the selector 170 through an output line L22 of the test input part 160. The transfer part 130 transfers transfer data applied to a transfer input terminal L24 to the transfer output terminal L30.

The comparing part 190 compares transfer data which is output through the transfer part 130 with reference pattern data Ref Data to detect whether the transfer part 130 is defective or not. The transfer data is applied to the comparing part 190 through a line L32. If the operation of the transfer part 130 is detected to be defective, a defect judgment signal of the transfer part 130 is output from an output terminal out 2 of the comparing part 190.

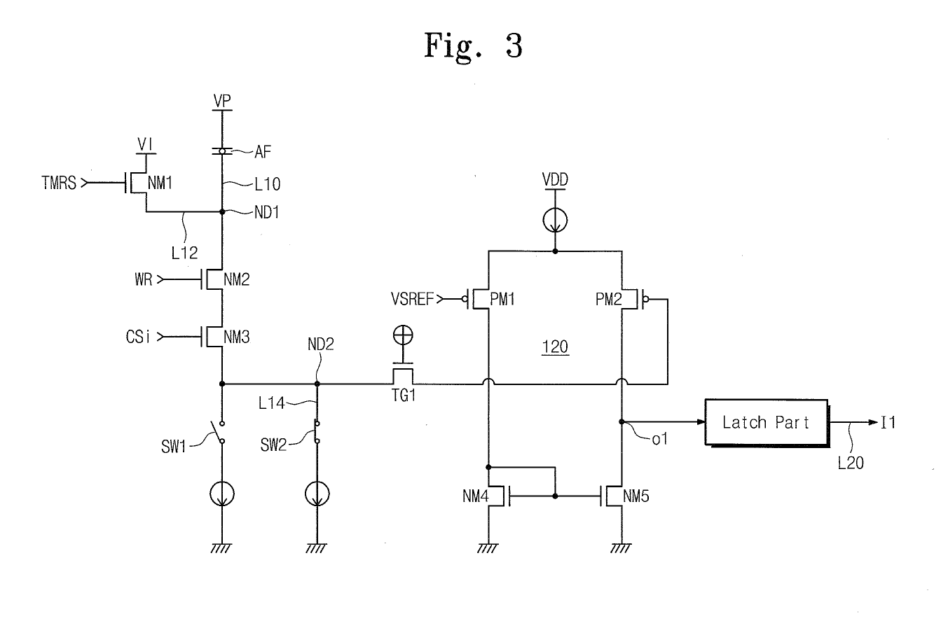

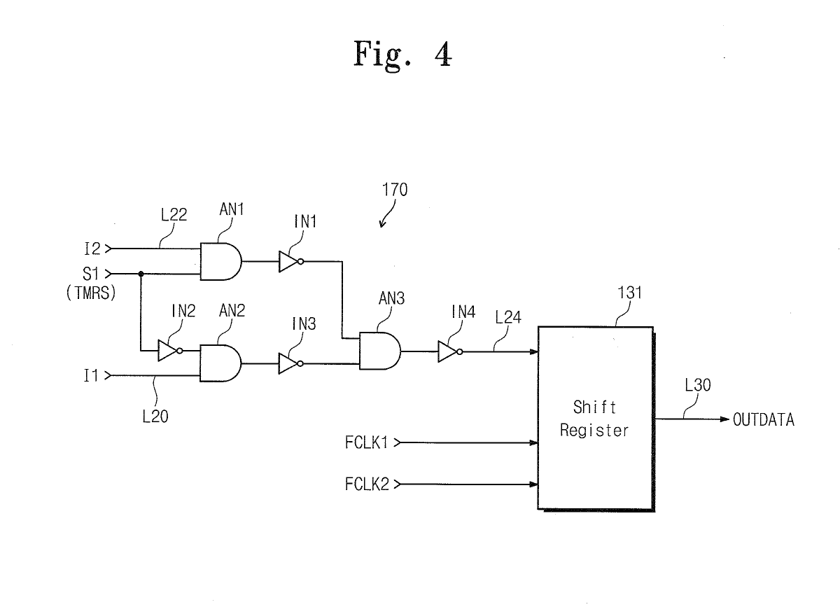

A testing operation for detecting whether internal circuit blocks such as the sensing part connected to the output terminal of the anti-fuse array 110 or the transfer part 130 connected to the sensing output terminal of the sensing part are defective or not will be described in detail with reference to FIGS. 3 and 4.

FIG. 3 is a detailed circuit diagram of internal circuit block of the anti-fuse circuit including a sensing amplifier as shown in FIG. 2.

Referring to FIG. 3, an anti-fuse AF in the anti-fuse array 110 is connected to a supply voltage terminal VP.

The anti-fuse AF is generally a resistance fuse device. The anti-fuse AF has a high resistance (e.g., 100MΩ) when it is not programmed and has a low resistance (e.g., 100MΩ) after it is programmed. The anti-fuse AF is formed of very thin dielectric material of several angstroms Å through several hundreds of angstroms Å such as composite of a dielectric substance such as silicon dioxide (SiO2), silicon nitride, tantalum oxide or silicon dioxide-silicon nitride-silicon dioxide (ONO) is sandwiched between two conductive materials.

A program operation of the anti-fuse AF is performed by applying a high voltage (e.g., 10V) through anti-fuses for a sufficiently long time to rupture the dielectric substance between two conductive materials. If the anti-fuse AR is programmed, conductive materials of both ends of anti-fuse are shorted and thereby the resistance through the anti-fuse AR becomes low. Thus, a initial state of anti-fuse is electrically ‘open’ state. And if a high voltage is applied to the anti-fuse, so that the anti-fuse is programmed, the anti-fuse enters an electrical ‘shorted’ state.

In FIG. 3, the anti-fuse AF is illustrated as one anti-fuse of the anti-fuse array 110 for convenience of illustration.

An N-type MOS transistor NM1 connected to a node ND1 through a line L12 may implement the test signal input part 140 of FIG. 2. The N-type MOS transistor NM1 can supply a voltage of set level to the node ND1 in response to a test mode register set (TMRS) signal applied to the gate of N-type MOS transistor NM1.

A second switch SW2 connected to a node ND2 through a line L14 may implement the adjusting part 150 of FIG. 2. The second switch SW2 closes when the sense amplifier 120 performs a sensing operation. The second switch SW2 is opened while the anti-fuse AF is programmed.

A sense amplifier including P-type MOS transistors PM1 and PM2 and N-type MOS transistors NM4 and NM5 may implement the sense amplifier 120 of FIG. 2. A sensing part includes the sensing part 120, a transmission gate TG and a latch part.

The N-type MOS transistors NM2 and NM3 function as a row select gate and a column select gate respectively.

The first switch SW1 is closed while the anti-fuse AF is programmed. That the anti-fuse AF is ‘programmed’ means that the anti-fuse is ruptured by a high voltage to have a logical state opposite to its initial state. The not ruptured state is the initial state (before being programmed).

In FIG. 3, the sensing part including the sense amplifier 120 is an internal circuit block of anti-fuse circuit. While testing whether the sensing part is defective or not, the anti-fuse AF is preferably not ruptured. Thus, the line L10 is in a floating state at the beginning. At this time, the N-type MOS transistors NM1 is activated by a test mode register set (TMRS) signal to be turned ON. If the N-type MOS transistors NM1 is turned ON, a voltage of set level is applied to the node ND1 and this voltage is applied to the gate of the P-type MOS transistors PM2 in the sense amplifier 120 through the select gates NM2 and NM3 (which are turned ON in response to a row select signal WR and a column select signal Csi), and through the transmission gate TG1.

The sense amplifier 120 is of current mirror type and compares the voltage applied to the gate of the P-type MOS transistor PM2 with a voltage applied to the gate of the P-type MOS transistor PM1 to output an amplified output to an output terminal o1.

When the voltage applied to the gate of the P-type MOS transistor PM2 is higher than a voltage applied to the gate of the P-type MOS transistor PM1, a low level voltage is output from the output terminal o1. The low level voltage can be converted into an high level voltage (inverted) while passing through the latch part. If an output of high level voltage is obtained from the latch output terminal L2, it is judged that an operation of the sensing part is not defective. However, if an output of low level voltage is obtained from the latch output terminal L2, it is judged that an operation of the sensing part is defective. When it is judged that an operation of the sensing part is defective, by controlling the amount of leakage currents through the switch SW2 or controlling a sensing reference value VSREF of the sense amplifier, the output of low level may be changed to the output of high level. In that case, defect of sense amplifier can be cured.

In the present embodiment, when a sensing operation is performed, a voltage applied to the node ND2 is set to 0.3V through 0.8V and a current is set to 1 μA through 24 μA. When a program operation is performed on the anti-fuse AF, several hundreds micro amperes may flow through the switch SW1.

Again referring to FIG. 3, the detection of whether the sensing part is defective or not is accomplished by the monitoring part 180 by monitoring a sensing output signal while anti-fuses AF in the anti-fuse array are in a not ruptured state. When obtaining a sensing output signal through the sense amplifier, a separate sensing part testing path (in the sensing part connected to an output terminal of the anti-fuse array) and a test signal is applied through the sensing part testing pass line L12.

In the exemplary embodiments of the inventive concept, while an anti-fuse is in a not ruptured state, it is detected whether internal circuit blocks constituting an anti-fuse circuit are defective or not. Since defective circuits may be effectively repaired within a specific control range by detecting a defect of internal circuit block, the percentage defective chips is minimized or reduced.

FIG. 4 is a detailed circuit diagram of internal circuit block of the anti-fuse circuit including a transfer part illustrated in FIG. 2.

In FIG. 4, a plurality of logical gates AN1-AN3, IN1-IN4 implement the selector 170 of FIG. 2, having a select output terminal L24. And a shift register 131 included in the transfer part 130 of FIG. 2 is also illustrated.

The select control signal S1 being applied to the selector 170 is preferably the test mode register set (TMRS) signal. If the select control signal S1 (TMRS) of logic “1” is applied, the test data I2 is loaded on the select output terminal L24. If the select control signal S1 (TMRS) of logic “0” is applied, the sensing data I1 is loaded on the select output terminal L24. The select control signal S1 (TMRS) of logic “1” is applied when it is time to check the operation of the shift register 131 for defects. If the select control signal S1 of logic “1” is applied, the sensing data I1 is blocked and the test data I2 is applied as the input of the shift register 131 at terminal L24. When the transfer part testing path L22 is activated by the select control signal S1 (TMRS) applied to the selector 170, the test data I2 is applied to the shift register 131 at terminal L24 and the sensing data I1 is blocked.

When testing the transfer part 130 for defects, a test is performed when the anti-fuse in the anti-fuse array 110 is in the not ruptured state.

The test data I2 may be a binary clock signal pattern alternating between a logical value of “0” and a logical value of “1”.

When test data being applied to the transfer input terminal L24 is “1010101010 . . . 10”, if transfer data OUTDATA obtained from the transfer output terminal L30 is “1010101010 . . . 10”, (i.e., the output is the same as the input) the operation of the transfer part 130 may be judged to be normal. However, if transfer data OUTDATA obtained from the transfer output terminal L30 is not “1010101010 . . . 10”, the operation of the transfer part 130 may be judged to be defective. The comparing part 190 of FIG. 2 compares the transfer data OUTDATA output through the transfer part 130 with the reference data Ref Data to detect defects in the operation of the transfer part 130. When an operation of the shift register 131 is detected to be defective, the comparing part 190 outputs a transfer part defect judgment signal to the output terminal out2.

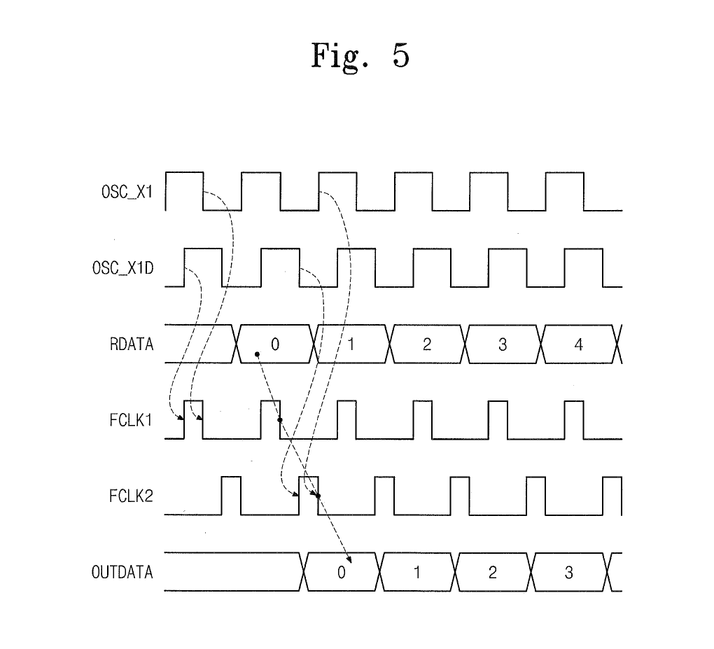

Clocks FCLK1 and FCLK2 are clocks having the same frequency but different phases, applied to the shift register 131. Waveforms of the clocks FCLK1 and FCLK2 are illustrated in the timing diagrams of FIGS. 5 through 8.

Whether the transfer part is defective or not can be detected by forming a transfer part testing path in the transfer part connected to a sensing output terminal of the sensing part and monitoring transfer data obtained through the transfer part. In this case, while an anti-fuse in the anti-fuse array exists in a state that is not ruptured, test data is applied through the transfer part testing path.

FIGS. 5 through 8 are timing diagrams provided to explain an exemplary circuit operation of the circuit block shown in FIG. 4.

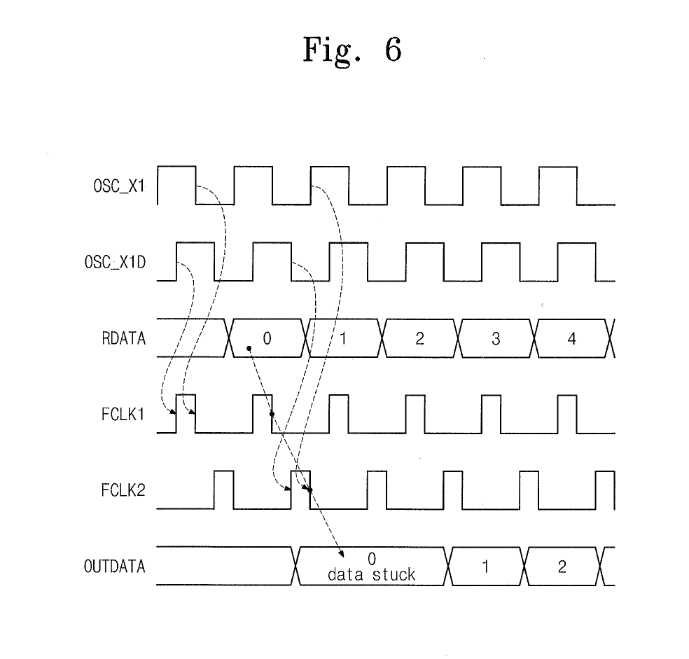

FIGS. 5 and 6 show circuit operation timings that can be observed when an anti-fuse in the anti-fuse array exists in a not-ruptured state without applying the input select scheme of FIG. 4.

Referring to FIG. 5, the clocks FCLK1 and FCLK2 are applied to the shift register 131 and program data RDATA obtained because anti-fuse cells are ruptured is transmitted to the sensing output terminal L20. In the case that the shift register 131 performs normally without defects, the output data OUTDATA is normally output like the waveform OUTDATA of FIG. 5. The first and second oscillating clocks OSC_X1 and OSC_X1D may generated in a semiconductor device to generate the clocks FCLK1 and FCLK2.

However, in the case that the shift register 131 has a defect affecting its operation, the output data OUTDAT may be abnormally output like the waveform OUTDATA shown FIG. 6. Referring to FIG. 6, in the case that the shift register 131 has a defect affecting its operation, a ‘data stuck’ phenomenon may occur like as shown by the waveform OUTDATA in FIG. 6.

In case of FIGS. 5 and 6, since an internal circuit block is tested while one or more of the anti-fuses AF in the anti-fuse array are in a ruptured state, this may not be the most desirable test method.

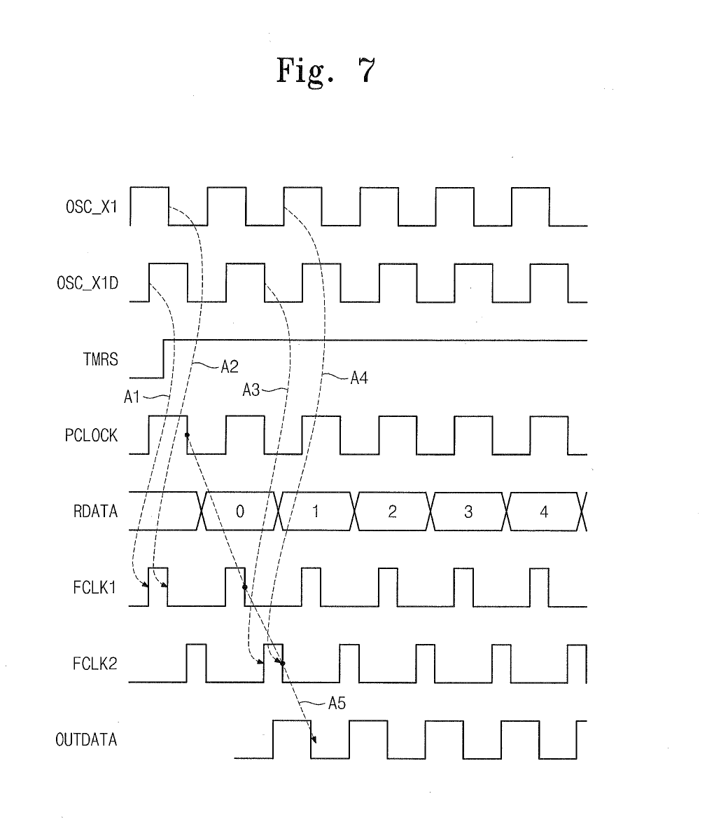

Referring to FIG. 7, a test mode register set (TMRS) signal applied as the control signal 51 in a nondestructive test operation has a high level. Since the sensing data I1 (RDATA) is blocked in the selector 170 while the waveform TMRS maintains a high level, the sensing data RDATA is ignored.

The clocks FCLK1 and FCLK2 are signals synchronized with a rising edge and a falling edge of the first and second oscillating clocks OSC_X1 and OSC_X1D respectively as indicated by arrows A1-A4. A waveform PCLOCK is preferably used as the test data I2 applied to the line L22. As indicated by an arrow A5, in the case that the transfer data the same as the waveform OUTDATA is obtained (the same as input test data PCLOCK), the comparing part 190 judges that the transfer part 130 is not defective.

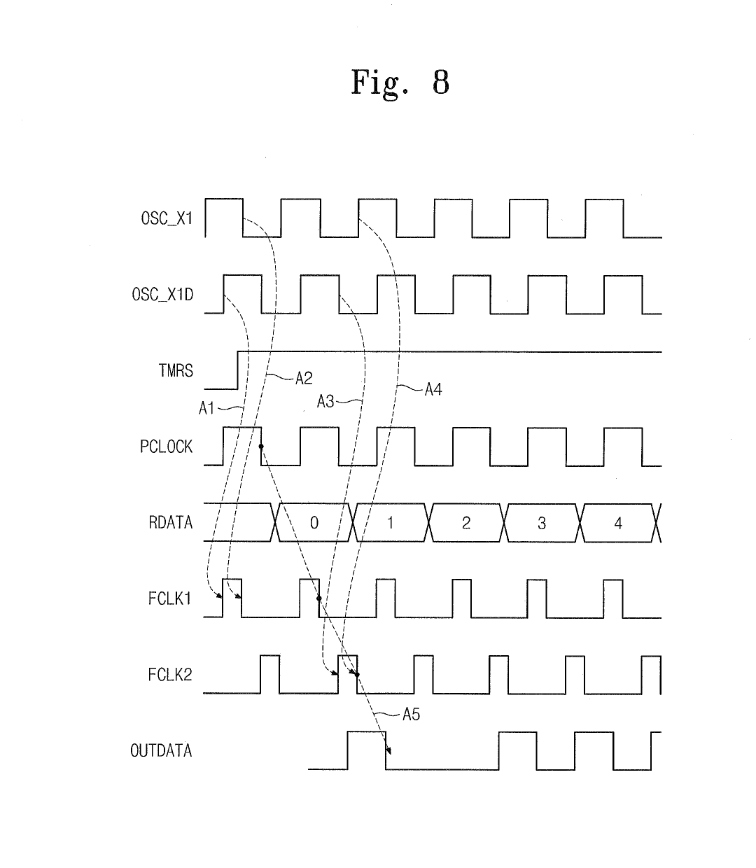

Referring to FIG. 8, in the case that erroneous transfer data (e.g., like waveform OUTDATA indicated by an arrow A5) is obtained, the comparing part 190 judges that the transfer part 130 is defective. This is because a logical state of the waveform OUTDATA is not the same as a delayed waveform PCLOCK.

In such a case, where a defect in the operation of the shift register 131 is detected, a defect curing scheme may be applied to the transfer part 130. A defect cure can be effectively realized by changing an internal control factor controlling a shifting operation of the shift register 131.

Whether an internal circuit block in FIG. 4 constituting an anti-fuse circuit is defective or not may be detected while the anti-fuse AF exists in a state that is not ruptured. Since defective circuits may be effectively repaired to operate normally within a specific control range after a defect of the transfer part is detected, the percentage defect of chips can be minimized or reduced.

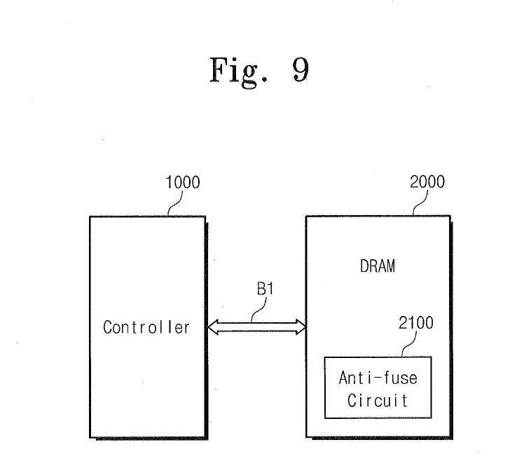

FIG. 9 is a block diagram of an exemplary embodiment of the inventive concept applied to a memory system.

Referring to FIG. 9, a memory system includes a controller 1000 and a DRAM 2000. A bus B1 is employed for transmission of addresses, data and commands between the controller 1000 and the DRAM 2000.

The DRAM 2000 includes the anti-fuse circuit structure like as shown in FIG. 2 as the anti-fuse circuit 2100. In that case, even while the anti-fuse exists in a initial state (i.e., not ruptured), it can be detected whether an internal circuit block constituting an anti-fuse circuit is defective or not. Since defective circuits can be effectively repaired to operate correctly within a specific control range when a defect of the internal circuit block is detected, the percentage defect of chips during manufacture of the DRAM 2000 is reduced. Thus, cost required to manufacture the memory system is reduced and reliability of the memory system is improved.

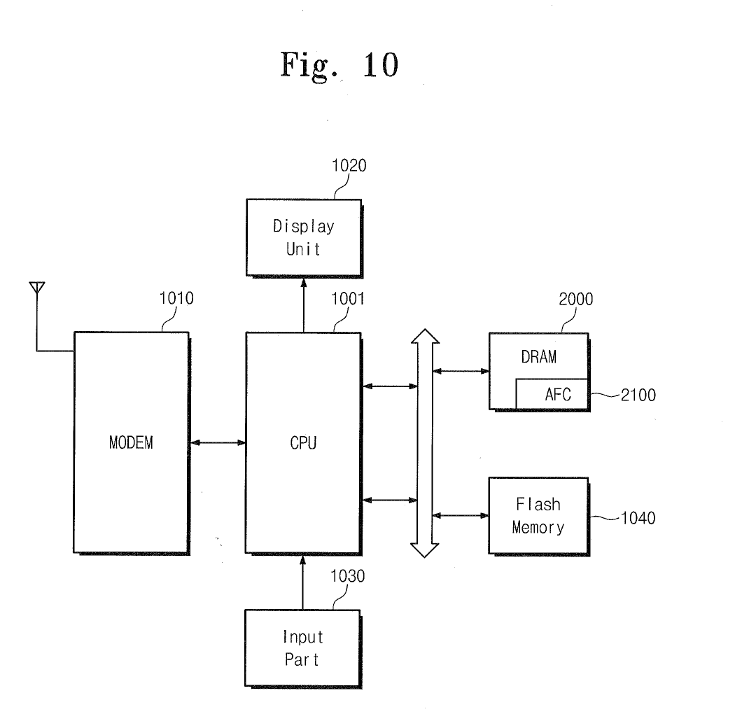

FIG. 10 is a block diagram illustrating an exemplary embodiment of the inventive concept applied to an electronic device.

Referring to FIG. 10, an electronic device includes a modem 1010, a CPU 1001, a DRAM 2000, a flash memory 1040, a display unit 1020 and an input unit 1030. The CPU 1001, the DRAM 2000 and the flash memory 1040 can be manufactured or packaged in one semiconductor chip. The DRAM 2000 includes an anti-fuse circuit 2100 having the circuit structure like as shown FIG. 2.

The modem 1010 performs a modulation/demodulation function for communication and transmission of data.

The CPU 1001 controls the overall operation of the electronic device according to the software program stored in the flash memory 1040.

The DRAM 2000 functions as a system memory of the CPU 1001 and may be a synchronous DRAM.

The flash memory 1040 may be a NOR-type flash memory or a NAND-type flash memory.

The display unit 1020 may be a device such as a liquid crystal having a backlight, a liquid crystal having an LED light source, or an OLED, or an SED, and may have a touch screen. The display unit 1020 functions as an output device displaying an image such as character, number, picture, etc. in color.

The input unit 1030 may be an input device including a number key, a function key, alphabet keys, etc. and performs an interface function between the electronic device and person.

The DRAM 2000 includes the anti-fuse circuit structure like as show in FIG. 2 as the anti-fuse circuit (AFC) 2100. Thus, while an anti-fuse AF exists in a state that is not programmed, whether or not internal circuit blocks constituting the anti-fuse circuit are defective can be easily detected. Since defective circuits may be effectively repaired to operate reliably within a specific control range when a defect of the internal circuit block is detected, the percentage defect of manufactured chips of the DRAM 2000 is reduced. Thus, cost required to manufacture the electronic device is reduced and performance of the electronic device is improved by increased reliability.

The electronic device can function as a mobile communication device or as a smart card or solid disk drive (SSD) by adding or subtracting constituent elements as desired.

The electronic device can be connected to an external communication device through a separate interface. The communication device may be a digital DVD player, a computer, a set top box (STB), a game machine, a digital camcorder, etc.

Although not illustrated in the drawing, an application chipset, a camera image processor (CIS), a mobile DRAM, etc. may be further provided to the electronic device.

The chip forming the electronic device can be mounted using various types of packages. The chip can be packaged by various types of packages such as Pop (package on package), ball grid array (BGA), chip scale package (CSP), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP) and wafer-level processed stack package (WSP).

Although a flash memory is adopted in FIG. 10 as an illustration, a other type of nonvolatile storage may be used. The nonvolatile storage can store data information having various types of data such as text, graphic, software code, etc. The nonvolatile storage may be implemented with an electrically erasable programmable read-only memory (EEPROM), a flash memory, a magnetic RAM (MRAM), a spin-transfer torque MRAM, a conductive bridging RAM, a ferroelectric RAM, a phase change RAM called an ovonic unified memory, a resistive RAM, a nanotube RAM, a polymer RAM, a nano floating gate memory (NFGM), a holographic memory, a molecular electronics memory device or an insulator resistance change memory.

According to the exemplary embodiments of the inventive concept, while an anti-fuse is in a state that is not ruptured, it can be detected whether internal circuit blocks constituting an anti-fuse circuit are defective or not. Since defective goods containing the disclosed anti-fuse circuit may be effectively repaired to useable goods within a specific control range when detecting defect of internal circuit block, the percentage defect of manufacturing the chip is reduced.

The foregoing is illustrative of the inventive concept and is not to be construed as limiting thereof. Although a few exemplary embodiments of the inventive concept have been described, those skilled in the art will readily appreciate that many modifications are possible in the embodiments without materially departing from the novel teachings of the present invention. Accordingly, all such modifications are intended to be included within the scope of the present invention as defined in the claims. The present invention is defined by the following claims, with equivalents of the claims to be included therein

What is claimed is:

1. A method of testing an anti-fuse circuit including a sense amplifier connected to the output terminal of an anti-fuse array, the method comprising:
forming a sensing part testing path in a sensing part of the anti-fuse circuit connected to the output terminal of the anti-fuse array, wherein the sensing part includes the sense amplifier configured to output a sensing output signal;
obtaining a sensing output signal through a sense amplifier by applying a test signal through the sensing part testing path while the anti-fuses in the anti-fuse array exists in a not-programmed state;
and detecting a defect in the operation of the sensing part by comparing the obtained sensing output signal with reference data.

2. The method of claim 1, further comprising adjusting a control factor of the sense amplifier if the detected defect of the operation of the sensing part is correctable by adjusting the control factor within an adjustable range.

3. The method of claim 2, wherein the control factor of the sense amplifier is an input leakage value of the sense amplifier.

4. The method of claim 2, wherein the control factor of the sense amplifier is a sensing reference value of the sense amplifier.

5. The method of claim 1, wherein the sensing part testing path is enabled by a test mode register set signal.

6. A method of testing an internal circuit block of an anti-fuse circuit including a sense amplifier connected to the output terminal of an anti-fuse array, the method comprising:
forming a transfer part testing path in a transfer part of the anti-fuse circuit, the transfer part being connected to a sensing output terminal of a sensing part of the anti-fuse circuit, the sensing part being configured to sense an output of the anti-fuse array;
obtaining transfer data through the transfer part by applying test data through the transfer part testing path; and
detecting a defect in the operation the transfer part by comparing the obtained transfer data with reference data.

7. The method of claim 6, further comprising adjusting a control factor of the transfer part if the detected defect of the operation of the transfer part is correctable by adjusting the control factor within a adjustable range.

8. The method of claim 6, wherein the transfer part testing path is enabled by a test mode register set signal.

9. The method of claim 6, wherein the test data and the reference data is a clock signal pattern.

10. The method of claim 8, wherein while the transfer part testing path is enabled, the test data is applied to the transfer part and data of the anti-fuse array is blocked.

11. An anti-fuse circuit of a semiconductor device comprising:
an anti-fuse array comprising a plurality of anti-fuses;
a sensing part connected to an output terminal of the anti-fuse array;
a transfer part connected to a sensing output terminal of the sensing part;
a test signal input part for providing a test signal to the output terminal of the anti-fuse array in response to an activation signal being applied when the anti-fuses in the anti-fuse array exist in a state that is not ruptured; and
a monitoring part for detecting defects in the operation of the sensing part by monitoring a sensing output signal while the sensing part receives the test signal, and configured to generate the sensing output signal at the sensing output terminal while the sensing part receives the test signal.

12. The anti-fuse circuit of claim 11, further comprising a test data input part for applying test data to the sensing output terminal when anti-fuses in the anti-fuse array exist in the not-ruptured state.

13. The anti-fuse circuit of claim 12, further comprising a selecting part for selectively applying one of the test signal and sensing data of the sensing output terminal to the transfer part according to a select control signal.

14. The anti-fuse circuit of claim 13, further comprising a comparing part for detecting a defect in the operation of the transfer part by comparing transfer data output through the transfer part with reference data.

15. The anti-fuse circuit of claim 14, wherein the semiconductor device of claim 11 is a volatile semiconductor memory device and wherein the anti-fuse circuit is connected to a row decoder of the volatile semiconductor memory device or to a column decoder of the volatile semiconductor memory device.

16. A semiconductor device comprising:
a non-volatile memory cell array, comprising a plurality of non-volatile memory cells;
a sensing part connected to an output terminal of the memory cell array; and
a test signal input part for providing a test signal to the output terminal of the memory cell array in response to an activation signal being applied when the memory cells exist in a state that is not programmed;

17. The device of claim 16, further comprising:
a transfer part connected to a sensing output terminal of the sensing part;
a monitoring part for detecting defects in the operation of the sensing part by monitoring a sensing output signal while the sensing part receives the test signal, and configured to generate the sensing output signal at the sensing output terminal while the sensing part receives the test signal.

18. The semiconductor device of claim 17, wherein each of the non-volatile memory cells is an anti-fuse.

19. The semiconductor device of claim 18, wherein the semiconductor device includes a volatile semiconductor memory device and wherein the non-volatile memory cell array is connected to a row decoder of the volatile semiconductor memory device or to a column decoder of the volatile semiconductor memory device.
